(19) United States
(12) Patent Application Publication
(10) Pub. No.: US 2017/0084528 A1
(43) Pub. Date: Mar. 23, 2017

(54) PACKAGE SUBSTRATE AND MANUFACTURING METHOD THEREOF

(71) Applicant: SAMSUNG ELECTRO-MECHANICS CO., LTD., Suwon-si (KR)

(72) Inventors: Sang-Youp LEE, Seoul (KR); Hang-Lim KIM, Busan (KR); Cheol-Ho CHOI, Hwaseong-si (KR)

(73) Assignee: SAMSUNG ELECTRO-MECHANICS CO., LTD., Suwon-si (KR)

(21) Appl. No.: 15/074,129

(22) Filed: Mar. 18, 2016

(30) Foreign Application Priority Data
Sep. 18, 2015 (KR) 10-2015-0132498

(51) Int. Cl. H01L 23/498; H01L 21/683; H01L 21/48

(52) U.S. Cl. CPC H01L 23/49838; H01L 23/49816; H01L 21/4853; H01L 21/6835; H01L 2221/68345

(57) ABSTRACT

A package substrate includes an encapsulating layer; a circuit pattern having an end embedded in the encapsulating layer; and a conductor disposed on a portion of the encapsulating layer, externally exposed, and electrically connected to the at least one end of the circuit pattern embedded in the encapsulating layer.

### CROSS-REFERENCE TO RELATED APPLICATIONS

This application claims the benefit under 35 USC 119(a) of Korean Patent Application No. 10-2015-0132498, filed with the Korean Intellectual Property Office on Sep. 18, 2015, the entire disclosure of which is incorporated herein by reference for all purposes.

### BACKGROUND

1. Field

The following description relates to a package substrate and a method of manufacturing the package substrate.

2. Description of Related Art

As electronic devices have become smaller, faster and more functional, new and various types of package substrates, which are used mainly for substrates for memory package, have been continuously introduced. Particularly, making these package substrates smaller and thinner has become an important objective, and there have been a number of studies for packaging a high capacity memory with a high density.

However, in the course of manufacturing a substrate for memory package, the substrate is warped if the substrate does not have a sufficient rigidity, and the possibility of warpage can be increased if the substrate is thinner. The warpage can be a major cause of lowered yield in the manufacture of a package-on-package product, and thus there has been a demand for a study for a package structure that can improve the productivity.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a package substrate includes an encapsulating layer; a circuit pattern having an end embedded in the encapsulating layer; and a conductor disposed on a portion of the encapsulating layer, externally exposed, and electrically connected to the at least one end of the circuit pattern embedded in the encapsulating layer.

Another end of the circuit pattern may protrude from a surface of the encapsulating layer or may be coplanar with a surface of the encapsulating layer. An insulating layer may be disposed on the encapsulating layer so as to cover the other end of the circuit pattern. The other end of the circuit pattern may then protrude from the insulating layer and may be coupled to a connection bump.

In another general aspect, a method of manufacturing a package substrate includes disposing an insulating layer on a surface of a carrier substrate, the insulating layer including an opening formed therein; disposing a circuit pattern within the opening of the insulating layer; externally exposing one end of the circuit pattern by reducing a thickness of the insulating layer; disposing an encapsulating layer on the insulating layer and the circuit pattern, wherein the one end of the circuit pattern is embedded in the encapsulating layer; removing a portion of the encapsulating layer in order to externally expose a portion of the one end of the circuit pattern embedded in the encapsulating layer; filling the removed portion of the encapsulating layer with a conductor, wherein the conductor is electrically connected with the portion of the one end of the circuit pattern; and removing the carrier substrate.

Disposing the encapsulating layer may include laminating the insulating layer and the circuit pattern with an encapsulating film; and curing the encapsulating film. The insulating layer may be removed after carrier substrate is removed. The circuit pattern may be etched in order to externally expose another end of the circuit pattern after the insulating layer is removed, wherein the other end of the circuit pattern and a surface of the encapsulating layer may be coplanar. After the carrier substrate is removed, another end of the circuit pattern may be externally exposed by removing a portion of the insulating layer and coupled to a connection bump.

Other features and aspects will be apparent from the following detailed description, the drawings, and the claims.

### BRIEF DESCRIPTION OF DRAWINGS

FIG. 1 illustrates a package substrate, according to an embodiment.

FIG. 2 illustrates a package substrate, according to another embodiment.

FIG. 3 illustrates a package substrate, according to a further embodiment.

FIG. 4 illustrates a package substrate, according to an embodiment.

FIG. 5 through FIG. 15 are processes of a method to manufacture a package substrate, according to an embodiment, by illustrating cross-sectional views of the package substrate during the manufacturing process.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

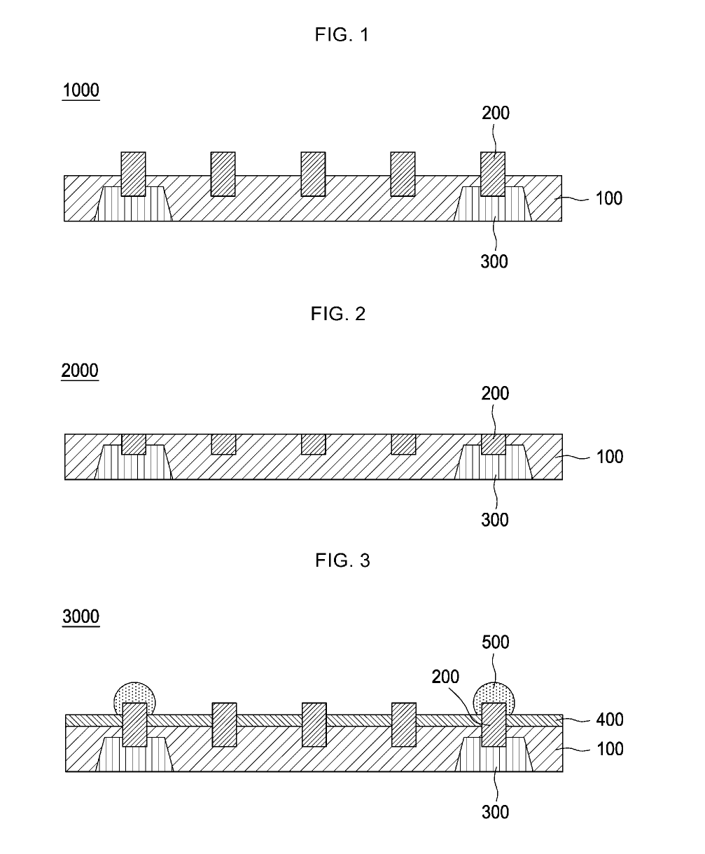

Hereinafter, certain embodiments of the present disclosure will be described in detail with reference to the accompanying drawings. Referring to FIG. 1, a package substrate 1000 includes an encapsulating layer 100, a circuit pattern 200 and a conductor 300. At least one end of the circuit pattern 200 is disposed within the encapsulating layer 100. The encapsulating layer stabilizes, protects, and insulates the circuit pattern 200. In this example, the encapsulating layer 100 may be a moldable material such as a film or a sheet.

The circuit pattern 200, which has at least one end thereof embedded in the encapsulating layer 100, forms an electric circuit for performing a predetermined function. In this example, the circuit pattern 200 may be formed through an etching process s using photolithography or an additive process (plating method), however the circuit pattern 200 may not necessarily be formed using the process described herein, and various other processes may be used to form the circuit pattern 200.

The conductor 300 is disposed on a portion of the encapsulating layer 100 in such a way that the conductor 300 is externally exposed. Additionally, the conductor 300 is electrically connected with the one end of the circuit pattern 200, and may function as a pad for electrical connecting the package substrate 1000 with another substrate or an electronic component.

Accordingly, in the package substrate 1000 in accordance with this example, the encapsulating layer 100 itself not only stabilizes and protects the circuit pattern 200 but also functions as an insulating member, without an additional insulating member. Thus, a thin package substrate may be realized.

Moreover, by utilizing a molded material, a much more improved rigidity may be achieved, compared to utilizing the conventional insulating material of epoxy resin, and thus it is possible to reduce warpage due to a thinner package substrate 1000.

Referring to FIG. 1, the circuit pattern 200 is disposed in the encapsulating layer 100 in such a way that the other end of the circuit pattern 200 protrudes out of a surface of the encapsulating layer 100. Accordingly, the circuit pattern 200 itself protruding out of the surface of the encapsulating layer 100 may function as a post, or terminal for connection with another substrate or an electronic component.

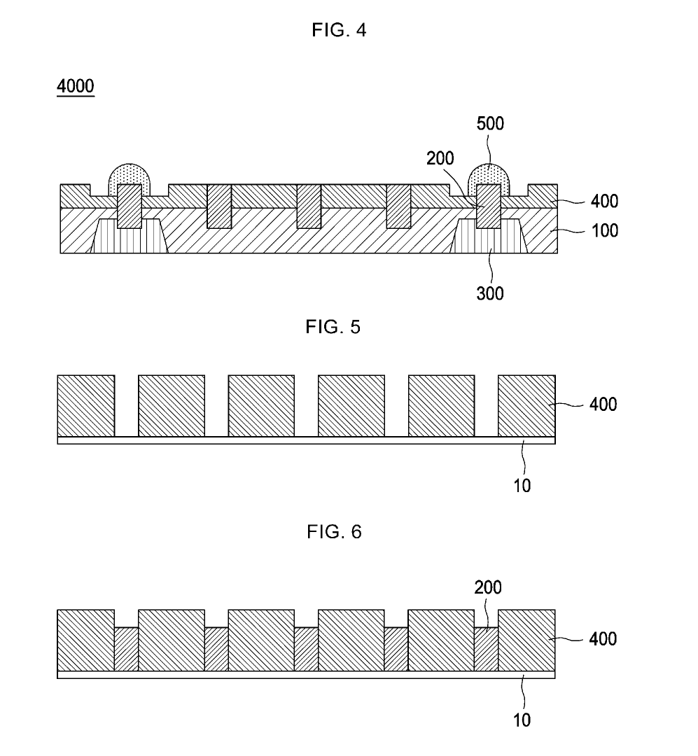

As illustrated in FIG. 2, in a package substrate 2000, according to an embodiment, a circuit pattern 200 is disposed in an encapsulating layer 100 in such a way that a surface of the circuit pattern 200 is exposed on a same plane as a surface of the encapsulating layer 100. For example, an upper surface of the circuit pattern 200 is coplanar with an upper surface of the encapsulating layer 100. In this example, an end of the circuit pattern 200 may be machined down, for example, by etching or polishing, so as to be coplanar as the surface of the encapsulating layer 100.

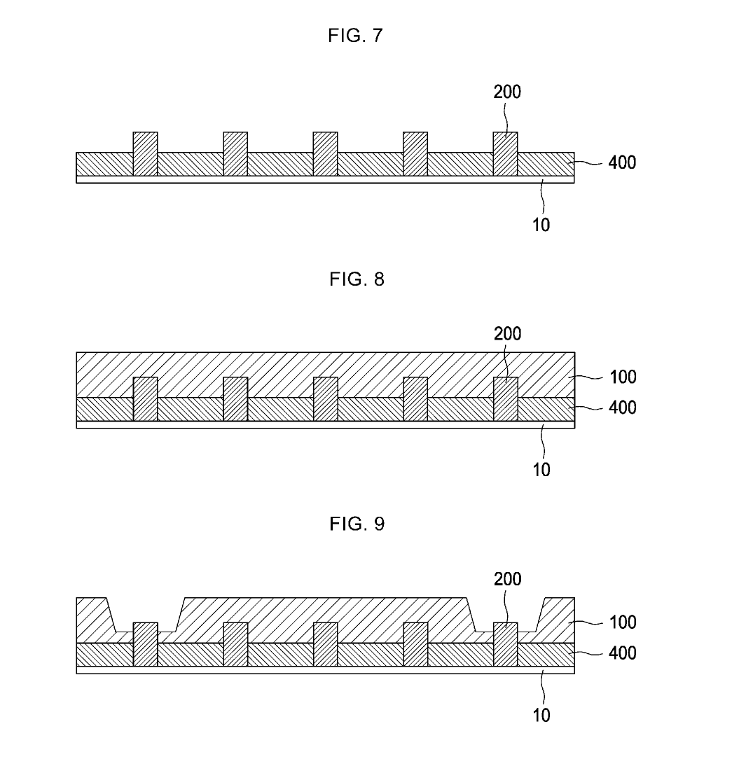

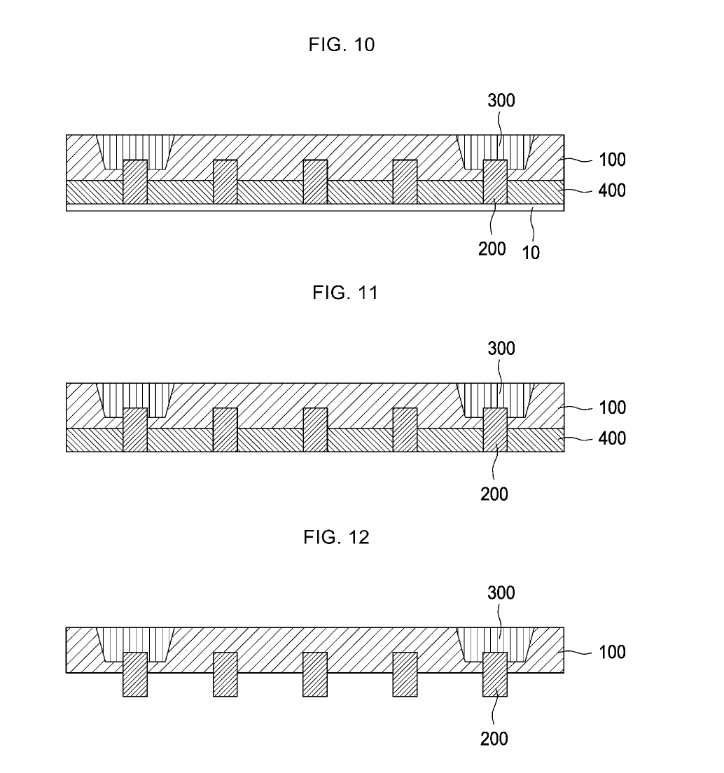

In the embodiments illustrated in FIG. 3 and FIG. 4, package substrates 3000, 4000, respectively, further include an insulating layer 400 disposed on an encapsulating layer. The end of the circuit pattern 200 protrudes from the insulating layer 400 and is coupled to a connection bump 500.

Referring to FIG. 3, a thickness of the insulating layer 400 is configured to expose one or more ends of the circuit pattern 200. The connection bump 500 is coupled to one or more ends of the circuit pattern 200. Alternatively, as shown in FIG. 4, the insulating layer 400 is partially removed at a portion where an end of the circuit pattern 200 is to be exposed, and the connection bump 500 is coupled to the exposed end of the circuit pattern 200.

As described above, the package substrates 2000, 3000, 4000 according to one or more embodiments may be disposed in various structures. A depth of the embedded circuit pattern 200 and an overall thickness of the package substrate 2000, 3000, 4000 may vary according to the structural configuration of the various structures.

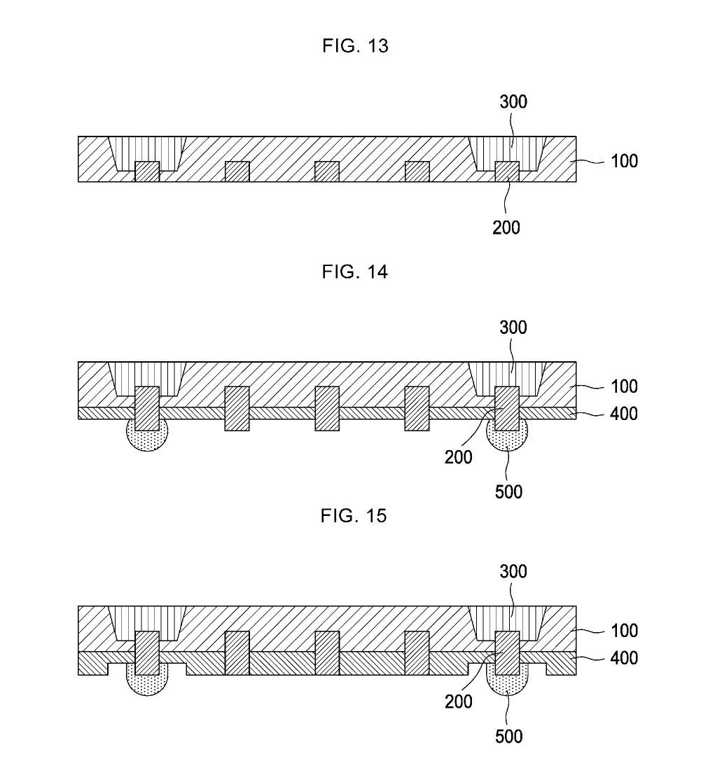

Referring to FIGS. 5 through 15, a method of manufacturing a package substrate, according to one or more embodiments, starts with forming an insulating layer 400, having at least one opening formed therein, on one surface of a carrier substrate 10 (see FIG. 5). The carrier substrate 10 is a member having a predetermined rigidity capable of functioning as a support fixture while a package substrate is manufactured. The carrier substrate 10 has a predetermined area or thickness, according to a shape of the package substrate.

The insulating layer 400 may be formed by coating a dry film or a solder resist film over the carrier substrate 10 and then removing a portion of the dry film or solder resist to form at least one opening exposing a portion of the carrier substrate 10. A circuit pattern 200 is formed within the at least one opening of the insulating layer 400 (see FIG. 6). In this example, the circuit pattern 200 may be formed by disposing a metal pattern in the opening of the insulating layer 400 using, for example, electroplating.

Referring to FIG. 7, one end of the circuit pattern 200 is externally exposed by reducing a thickness of the insulating layer 400. In this example, the thickness of the insulating layer 400 may be reduced enough to expose one end of the circuit pattern 200 to the outside by, for example, etching or photolithography.

Referring to FIG. 8, an encapsulating layer 100 is disposed on the insulating layer 400 and the circuit pattern 200 such that one end of the circuit pattern 200 is embedded within the insulating layer 400. The encapsulating layer 100 may stabilize and protect the circuit pattern 200 as well as a function as an insulator.

In this example, the encapsulating layer 100 may be made of a film or a sheet, having pliant properties, in order to function as the insulating member. In other words, the encapsulating layer 100 may be formed by laminating, or molding, an encapsulating film around the insulating layer 400 and the circuit pattern 200, and curing the encapsulating film. By using a film or a sheet as the encapsulating layer 100, the laminating process may be performed more readily, and adhesion between the circuit pattern 200 and the encapsulating layer 100 may be made through the curing process.

Referring to FIG. 9, a portion of the encapsulating layer 100 is removed such that at least one end of the circuit pattern 200 embedded in the encapsulating layer 100 is exposed. In this example, a portion of the encapsulating layer 100 may be removed using a laser process or any other process as long as the circuit pattern 200 is not affected by the process used for removing the portion of the encapsulating layer 100.

Referring to FIG. 10, the removed portion of the encapsulating layer 100 is filled with a conductor 300 so as to be electrically connected with the circuit pattern 200. In this example, the conductor 300 may be formed by filling the removed portion of the encapsulating layer 100 with a conductor, for example copper paste, or by a plating process. The conductor 300 adheres to the circuit pattern 200 through a curing process. The conductor 300 may function as a pad for electrically connecting the package substrate with another substrate or an electronic component, and the circuit pattern 200 itself may function as a plated through hole (PTH), which has been used in the conventional core layer structure.

Referring to FIG. 11, the carrier substrate 10 is removed. That is, manufacturing of the package substrate 1000, in accordance with an embodiment, is completed by removing the carrier substrate 10 that has been temporarily used for manufacturing the package substrate 1000.

As described above, since the encapsulating layer 100 itself carries out the function of stabilizing and protecting the circuit pattern 200, as well as, the function as an insulating member, the method of manufacturing a package substrate in accordance with an embodiment readily manufactures a thin package substrate 1000, without the use of an insulating member. Moreover, by utilizing a moldable material, a much more improved rigidity may be provided, compared to utilizing the conventional insulating material of epoxy resin, and thus it is possible to prevent warpage caused by making the package substrate 1000 thinner.

Referring to FIG. 12, the insulating layer 400 may be removed after removing the carrier substrate 10. Accordingly, the circuit pattern 200 is embedded in the encapsulating layer 100 in such a way that an end of the circuit pattern 200 protrudes from a surface of the encapsulating layer 100, allowing the circuit pattern 200 itself to protrude from the surface of the encapsulating layer 100 to function as a post, or terminal, for connection with another substrate or electronic component. After removing the insulating layer 400, the circuit pattern 200 is etched such that the end of the circuit pattern 200 is coplanar with the encapsulating layer 100.

Alternatively, after removing the carrier substrate 10, the other end of the circuit pattern 200 is externally exposed by removing a portion of the insulating layer 400, and a connection bump 500 is coupled to the other end of the circuit pattern 200. Specifically, a thickness of the insulating layer 400 may be reduced to expose at least one end of the circuit pattern 200, and the connection bump 500 is coupled to one or more of the at least one end of the circuit pattern 200 (see FIG. 14). In another embodiment, the insulating layer 400 is partially removed at portions adjacent to the circuit pattern 200 in order to externally expose the an end of the circuit pattern 200, and a connection bump 500 is coupled to the end of the circuit pattern 200 (see FIG. 15).

As described above, with the method of manufacturing a package substrate in accordance with one or more embodiments, the package substrate may be varied by considering a depth of burying the circuit pattern 200 and an overall thickness of the package substrate.

As a non-exhaustive example only, a device as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A package substrate comprising:
an encapsulating layer;
a circuit pattern comprising an end embedded in the encapsulating layer; and
a conductor disposed on a portion of the encapsulating layer, externally exposed, and electrically connected to the at least one end of the circuit pattern embedded in the encapsulating layer.

2. The package substrate of claim 1, wherein another end of the circuit pattern protrudes from a surface of the encapsulating layer.

3. The package substrate of claim 1, wherein another end of the circuit pattern is coplanar with a surface of the encapsulating layer.

4. The package substrate of claim 1, further comprising:
an insulating layer disposed on the encapsulating layer so as to cover another end of the circuit pattern,
wherein the other end of the circuit pattern protrudes from the insulating layer and coupled to a connection bump.

5. A method of manufacturing a package substrate, comprising:
disposing an insulating layer on a surface of a carrier substrate;
disposing a circuit pattern within an opening of the insulating layer;
externally exposing one end of the circuit pattern by reducing a thickness of the insulating layer;
disposing an encapsulating layer on the insulating layer and the circuit pattern, wherein the one end of the circuit pattern is embedded in the encapsulating layer;
removing a portion of the encapsulating layer to externally expose a portion of the one end of the circuit pattern embedded in the encapsulating layer;
filling the removed portion of the encapsulating layer with a conductor, wherein the conductor is electrically connected with the portion of the one end of the circuit pattern; and
removing the carrier substrate.

6. The method of claim 5, wherein disposing the encapsulating layer comprises:
laminating the insulating layer and the circuit pattern with an encapsulating film; and
curing the encapsulating film.

7. The method of claim 5, further comprising removing the insulating layer after carrier substrate is removed.

8. The method of claim 7, further comprising etching the circuit pattern to externally expose an other end of the circuit pattern after the insulating layer is removed,
wherein the other end of the circuit pattern and a surface of the encapsulating layer are coplanar.

9. The method of claim 5, further comprising, after the carrier substrate is removed:
externally exposing an other end of the circuit pattern by removing a portion of the insulating layer; and
coupling a connection bump to the other end of the circuit pattern.
